(19) United States
(12) Patent Application Publication
(10) Pub. No.: US 2013/0014819 A1
(43) Pub. Date: Jan. 17, 2013

(54) METHOD FOR DOPING A SEMICONDUCTOR SUBSTRATE, AND SOLAR CELL HAVING TWO-STAGE DOPING

(71) Applicants: Andreas Teppe, Konstanz (DE); Matthias Geiger, Neu-Ulm (DE); Reinhold Schlosser, Muenchen (DE); Adolf Muenzer, Unterschleissheim (DE); Jan Schoene, Reichenau (DE); Joerg Isenberg, Freiburg (DE); Tino Kuehn, Leipzig (DE); Steffen Keller, Konstanz (DE)

(72) Inventors: Andreas Teppe, Konstanz (DE); Matthias Geiger, Neu-Ulm (DE); Reinhold Schlosser, Muenchen (DE); Adolf Muenzer, Unterschleissheim (DE); Jan Schoene, Reichenau (DE); Joerg Isenberg, Freiburg (DE); Tino Kuehn, Leipzig (DE); Steffen Keller, Konstanz (DE)

(73) Assignee: CENTROTHERM PHOTOVOLTAICS AG, BLAUBEUREN (DE)

(21) Appl. No.: 13/582,499

(22) PCT Filed: Mar. 3, 2011
(86) PCT No.: PCT/DE2011/075033

§ 371 Date: Oct. 1, 2012

(30) Foreign Application Priority Data
Mar. 3, 2010 (DE) 102010010221.0
Mar. 9, 2010 (DE) 102010010813.8

(51) Int. Cl. H01L 31/0236; H01L 31/18

(52) U.S. Cl. 136/256; 438/98; 257/E31.124

(57) ABSTRACT

A method for doping a semiconductor substrate includes heating the semiconductor substrate by irradiation with laser radiation and at the same time diffusing dopant from a dopant source into the semiconductor substrate in heated regions. The semiconductor substrate is heated by the irradiation with laser radiation. A surface portion of the semiconductor substrate that is less than 10% of the total surface of all irradiated regions is melted and recrystallized. There is also provided a solar cell.

The invention concerns a method for doping a semiconductor substrate in accordance with the preamble to claim 1 and also a solar cell in accordance with the preamble of claim 12.

Prior art includes the heating of a semiconductor substrate using laser beams and thereby diffusing dopant from a dopant source into the semiconductor substrate. In particular, it has been suggested that such a method is used in the manufacture of selective emitters. In laser diffusions of this type, the surface of a semiconductor substrate is melted. At the same time dopant from a dopant source arranged nearby is diffused into the melted semiconductor substrate, which is subsequently cooled and recrystallised. As a result, heavier doping occurs in the melted and recrystallised region of the semiconductor substrate than in surrounding regions of the semiconductor substrate. Locally heavier dopings of this type and selective emitters created therefrom are supposed to have an advantageous effect on the efficiency of solar cells. However, it has emerged that due to the melting and subsequent recrystallisation, structural defects are formed in the semiconductor substrate which have a negative effect on efficiency and may overcompensate for the advantage of the dopant application. There is also the risk that unwanted impurities may be input into the semiconductor substrate, which reduce the efficiency of the manufactured solar cells.

To avoid these negative effects, WO 2006/012840 proposes a method in which the laser beam used is focused on the semiconductor substrate in a line focus, which is time-consuming to produce, with a high aspect ratio, i.e. with a height which is greater by orders of magnitude than the width of the line focus. This method and the equipment requirements to carry it out are time-consuming and hence cost-intensive.

The present invention is therefore based on the problem of providing a method according to the preamble of claim 1, with which the input of defects into the semiconductor substrate can be economically reduced.

This problem is solved by a generically defined method with the characteristic features of claim 1.

The invention is further based on the problem of providing a solar cell with a two-stage doping, which can be produced economically and has improved efficiency.

This problem is solved by a solar cell with the features of claim 12.

Advantageous refinements are the subject matter of the respective dependent claims.

The method according to the invention for doping a semiconductor substrate provides that the semiconductor substrate is heated by irradiation and at the same time dopant from a dopant source is thereby diffused into heated regions in the semiconductor substrate. When the semiconductor substrate is heated by irradiation with laser radiation, a surface portion of the semiconductor substrate which amounts to less than 10% of the total area of all irradiated regions is melted and recrystallised.

Consequently, only a minor surface portion of the regions of the semiconductor substrate heated by laser radiation is melted and recrystallised. This largely prevents the melting and recrystallisation which are critical with respect to the formation of defects. Surprisingly, it has emerged that in this way, in those heated regions in which no melting with subsequent crystallisation takes place, a dopant application is possible which achieves quality good enough for the formation of two-stage dopings, in particular the formation of selective emitters. Also, dopant is diffused into these heated regions, and its surface concentration is increased, which leads to a reduced contact resistance.

More heavily doped regions of a selective emitter serve to produce good electrical conductivity between a solar cell substrate used as semiconductor substrate and a metallisation arranged thereon and thus largely prevent dissipation losses of the electricity generated. While it has been assumed until now in the state of the art that to do this, a significant sheet resistance reduction is necessary in the more heavily doped regions, it has unexpectedly emerged that, using the method according to the invention, even with a comparatively small reduction in sheet resistance, the contact resistance can be greatly reduced, so that the desired good electrical conductivity can be realised between the solar cell substrate and a metallisation arranged thereon, hence the associated contact resistance can be reduced.

The semiconductor substrate can be directly irradiated with laser radiation. Alternatively, a layer arranged on the semiconductor substrate can be irradiated, for example a layer of phosphorus or borosilicate glass, which will henceforth be referred to for short as a P- or B-glass layer. In the second case, although the layer arranged on the semiconductor substrate can be irradiated directly, depending on the wavelength of the laser radiation used and the thickness of the sheet used, laser radiation can nevertheless enter the surface of the semiconductor substrate, be absorbed there and provide heating of the semiconductor substrate. In addition, or alternatively, heat transmission from the layer arranged on the semiconductor substrate into adjacent regions of the semiconductor substrate can bring about heating of the semiconductor substrate in regions adjacent the irradiated area.

For example, the P-glass- or B-glass layers already mentioned, arranged on the semiconductor substrate, can serve as dopant source. The way this is applied to the semiconductor substrate is immaterial. If silicon substrates are used as semiconductor substrates, they can, for example, be formed by phosphorus or boron diffusions of prior art. An alternative dopant source is a solution containing dopant which can be arranged on the semiconductor substrate. There is also the possibility, inter alia, of arranging the semiconductor substrate in an atmosphere containing dopant during the irradiation.

In practice, it has proven effective to heat the semiconductor substrate locally by means of local irradiation with laser radiation and to diffuse dopant locally into the heated regions. In this way economical two-stage doping structures can be formed, in particular two-stage emitters of solar cells, often referred to as selective emitters.

In one advantageous variant embodiment of the method according to the invention, the semiconductor substrate is not melted during irradiation with laser radiation. Until now, it would have been assumed that no two-stage dopings could be produced in this way. However, it has been shown that even if melting is completely prevented and hence also the recrystallisation, which is critical with respect to the formation of defects in more heavily doped regions of a two-stage or multi-stage doping, good contact resistances can be produced.

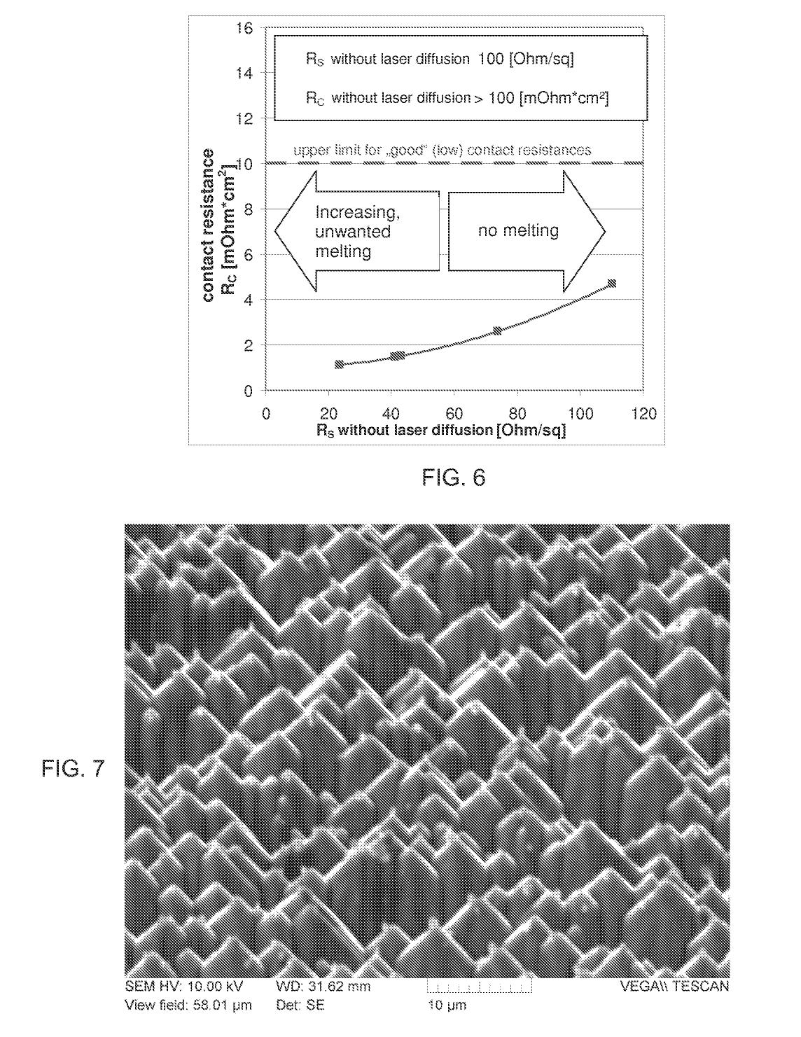

FIG. 6 illustrates this on the basis of test results. In the tests on which these results are based, silicon discs, which had a sheet resistance Rₛ of (100±10) Ω/sq before local irradiation with laser radiation, referred to here as laser diffusion for short, formed the starting point. The contact resistance R_{c} before laser diffusion was over 100 mΩcm².

As can be deduced from FIG. 6, after laser diffusion, even when melting was prevented and with an almost unchanged sheet resistance in the heated regions, the result was good contact resistances of clearly below 10 mΩcm². As the reduction in the sheet resistance increased, the undesirable melting and the risk of input of defects also increased, but contact resistance changed only slightly. This shows that with the method according to the invention, two-stage dopings with good quality can be produced while largely or even completely avoiding melting and recrystallisation of the semiconductor substrate. There is no longer any need for time-consuming methods, such as the realisation of a line focus and the associated costs. Instead, laser beam geometries which are simple to realise, such as round, square or rectangular beam geometries with a low aspect ratio, Gaussian or flat-top profiles can be used. In contrast to the line focus known in the art, it is also possible to do without expensively produced optical components.

In the manufacture of solar cells, the contact resistances achieved following laser diffusion allow electrical contacts with good conductivity to be formed between the semiconductor substrate and metallic screen printing pastes, so that the efficiency of the solar cells can be improved economically. If, also, the sheet resistance in the heated regions is not reduced, or reduced only slightly, the spectral sensitivity of these regions remains comparatively high, despite the reduced contact resistance, which also improves efficiency, provided light can shine onto partial regions of the heated regions.

If silicon substrates are used as semiconductor substrates, in particular silicon discs, a green laser beam has proven effective, especially one with a wavelength of 515 nm or 532 nm.

One refinement of the method according to the invention provides that a semiconductor substrate provided in at least some sections with a surface texturing is used and irradiation with laser radiation causes structure tips of the surface texturing to melt over a cross-sectional area of less than 1 μm², preferably over a cross-sectional area of less than 0.25 μm². Melted parts of the structure tips are subsequently recrystallised. Said cross-sectional area extends roughly perpendicularly to the direction of incidence of the laser radiation. The surface texturing can in principle be formed in any manner known in the art, in particular wet-chemically.

Preferably, mono- or multicrystalline silicon discs are used as semiconductor substrates and the surface texturing is formed using an alkaline or acid etching solution. As a result of the surface texturing, light injection into the semiconductor substrate can be increased, which has an advantageous effect on the efficiency of solar cells.

In one preferred variant embodiment of the method according to the invention, more heavily doped regions of a two-stage doping are formed by the local diffusion of dopant into the heated regions. As a result, with only minor input of defects into the semiconductor substrate, economical two-stage dopings can be produced, in particular two-stage emitter dopings referred to as selective emitters. These in turn enable the production of more efficient solar cells. The less heavily doped regions of the two-stage doping can, for example, be formed by a planar diffusion carried out before the application of the method, in particular by a diffusion of dopant from a solution containing dopant applied to the semiconductor substrate or by a pipe diffusion. Advantageously, in the subsequent local diffusion of dopant into the heated regions, the sheet resistance, as described above, is not reduced, or only slightly reduced, so that the spectral sensitivity in more heavily doped regions is largely maintained. This makes it possible, if need be with a slightly reduced efficiency of the solar cell, to make the more heavily doped regions broader than a metallisation subsequently formed on the more heavily doped regions, so that the adjustment of the metallisation relative to the more heavily doped regions can be made with less accuracy. As a result, the solar cell production process can be structured more economically and its rejection rate reduced.

A silicon disc is preferably used as semiconductor substrate or solar cell substrate in the method according to the invention, as well as in the solar cell according to the invention.

The method according to the invention is simple to integrate into existing production processes for semiconductor components. In particular, it can be economically integrated into known solar cell production processes and be combined with further process steps, as the cell front side can be processed independently of the cell back side. So it is possible, for example, using the method according to the invention, to form a selective emitter on the front side of the solar cells and to passivate their back sides by means of dielectric sheets or a series of dielectric sheets.

The solar cell according to the invention has a solar cell substrate at least partially provided with a surface texturing and a two-stage doping. Furthermore, in more heavily doped regions of the two-stage doping, structure tips of the surface texturing are melted and recrystallised over a cross-sectional area of less than 1 μm². Structure tips in this case means objects whose cross-sections taper at least partially with increasing distance from the solar cell substrate.

Such a solar cell can be economically manufactured using the method according to the invention. The surface texturing and the two-stage doping, which is preferably executed as selective emitter, enable a high degree of efficiency. Since the structure tips of the surface texturing are melted and recrystallised over a cross-sectional area of less than 1 μm², low defect densities can be realised in more heavily doped regions, which has a positive effect on the efficiency of the solar cell.

In one refinement of the solar cell according to the invention, the solar cell substrate has a contact resistance of 10 mΩcm² or less in the more heavily doped regions of the two-stage doping. Furthermore, in the more heavily doped regions of the two-stage doping it has a sheet resistance which is at least 50% of the sheet resistance value prevailing in the less heavily doped regions of the two-stage doping, preferably at least 70% and especially preferably at least 90% of the sheet resistance value prevailing in the less heavily doped regions of the two-stage doping. This enables good spectral sensitivity of the solar cell substrate in the more heavily doped regions and thus an improvement in efficiency.

One advantageous variant embodiment of this refinement provides that metallisations formed on the more heavily doped regions are narrower than the more heavily doped regions on which they are formed. As a result, when the solar cells are in operation, light falls on parts of the more heavily doped regions. Because of the only moderate to slightly reduced sheet resistance in the more heavily doped regions, however, these have good spectral sensitivity, so that compared with narrower more heavily doped regions, at most slight losses of efficiency result. Because the more heavily doped regions are wider compared with the metallisations, however, the production advantages explained above give rise to a lesser accuracy requirement in the adjustment or alignment of the metallisations with respect to the associated more heavily doped regions of the two-stage doping.

The invention will next be explained in more detail on the basis of some figures. Wherever expedient, elements with the same effect have been given the same reference numbers. The figures show:

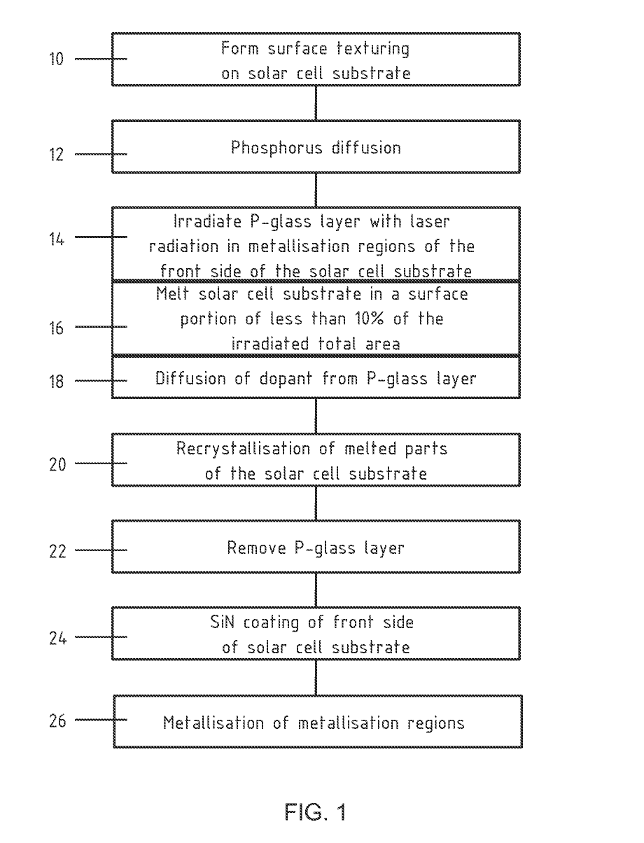

FIG. 1 Simplified diagram of a first embodiment of the method according to the invention

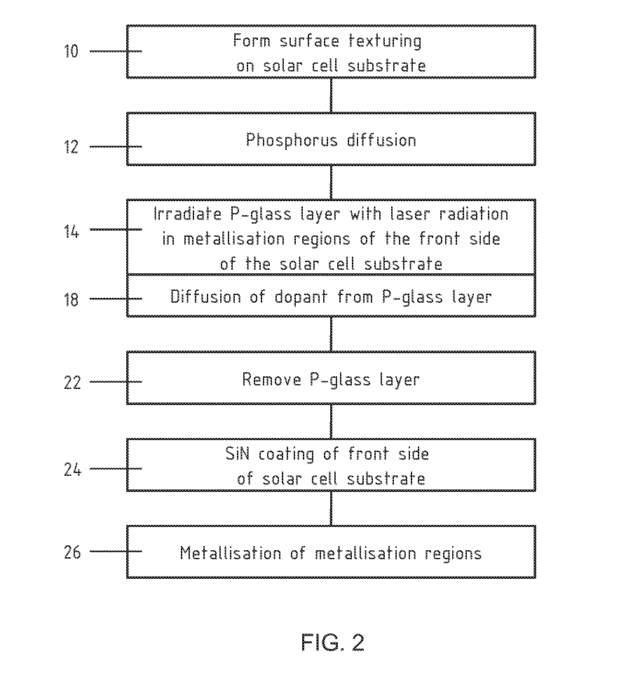

FIG. 2 Simplified diagram of a second embodiment of the method according to the invention, wherein the semiconductor substrate is not melted.

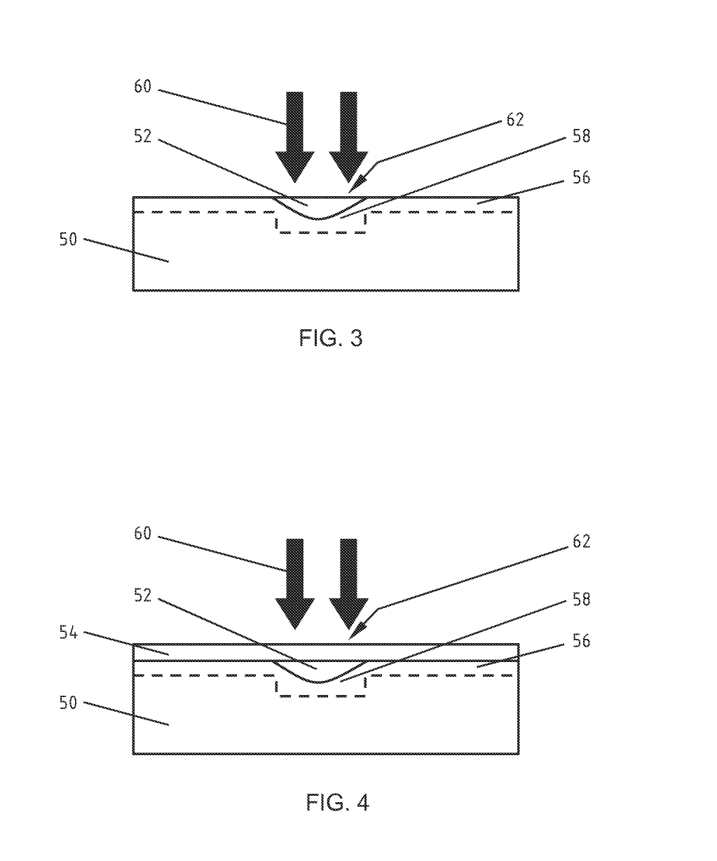

FIG. 3 Schematic diagram of a first variant of the irradiation with laser radiation in accordance with the method according to the invention

FIG. 4 Schematic diagram of a second variant of the irradiation with laser radiation in accordance with the method according to the invention

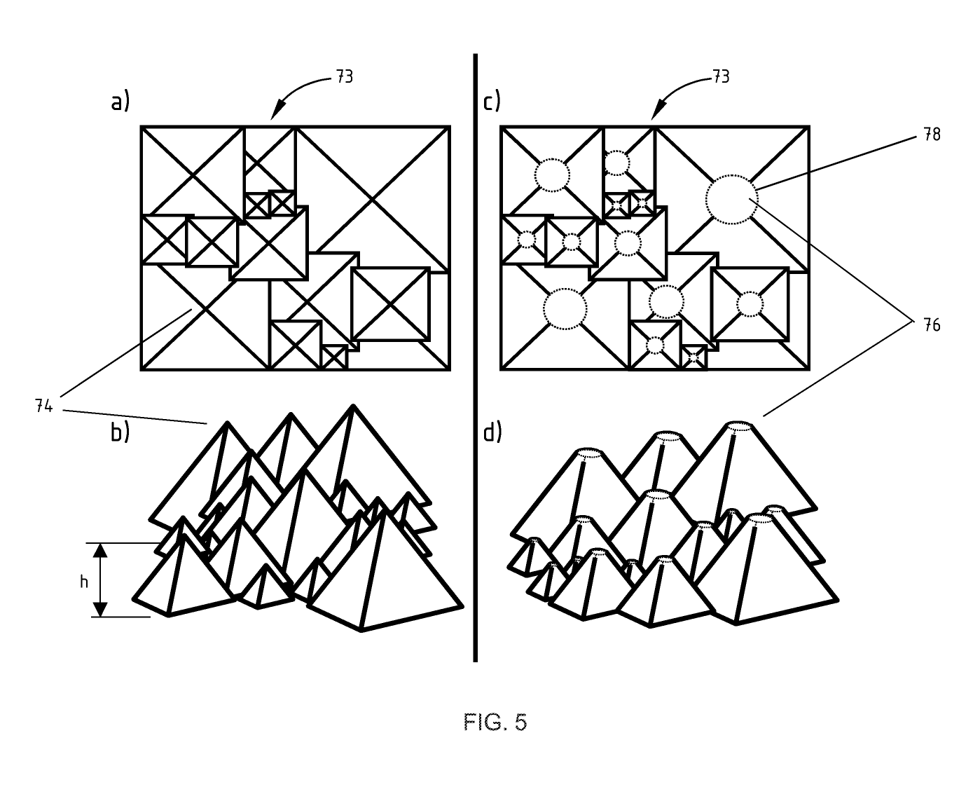

FIG. 5 Schematic diagram of a surface texturing with and without melted structure tips

FIG. 6 Contact- and sheet resistances after carrying out the method according to the invention

FIG. 7 Scanning electron microscope image of a semiconductor substrate with surface texturing after carrying out the method according to the invention

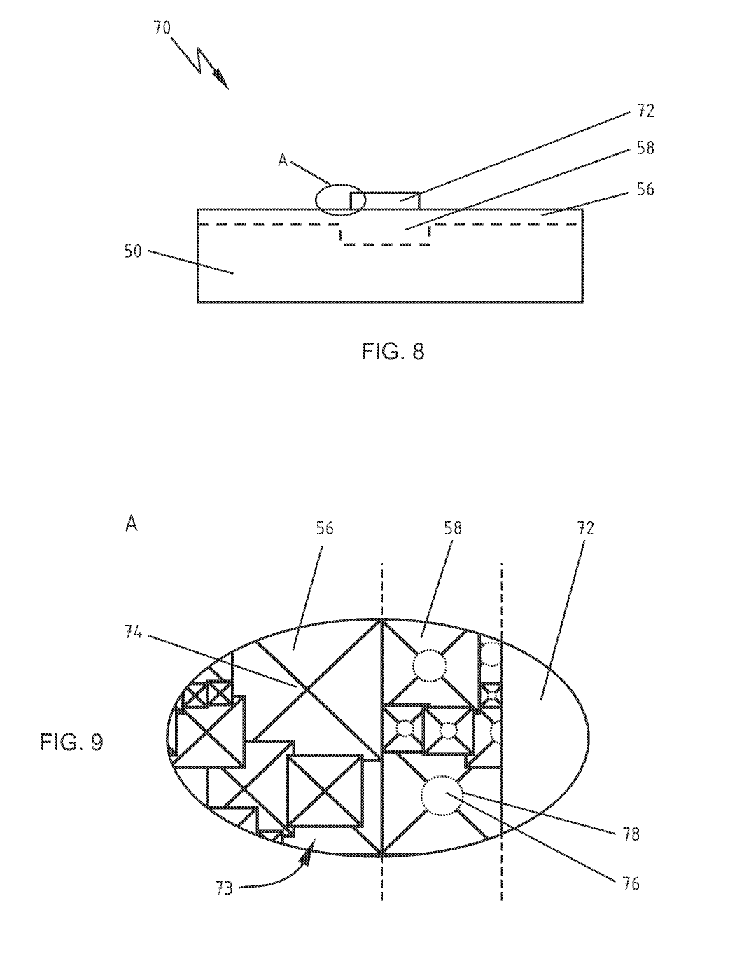

FIG. 8 An embodiment of a solar cell according to the invention

FIG. 9 Enlarged partial illustration of a top view of the solar cell from FIG. 8

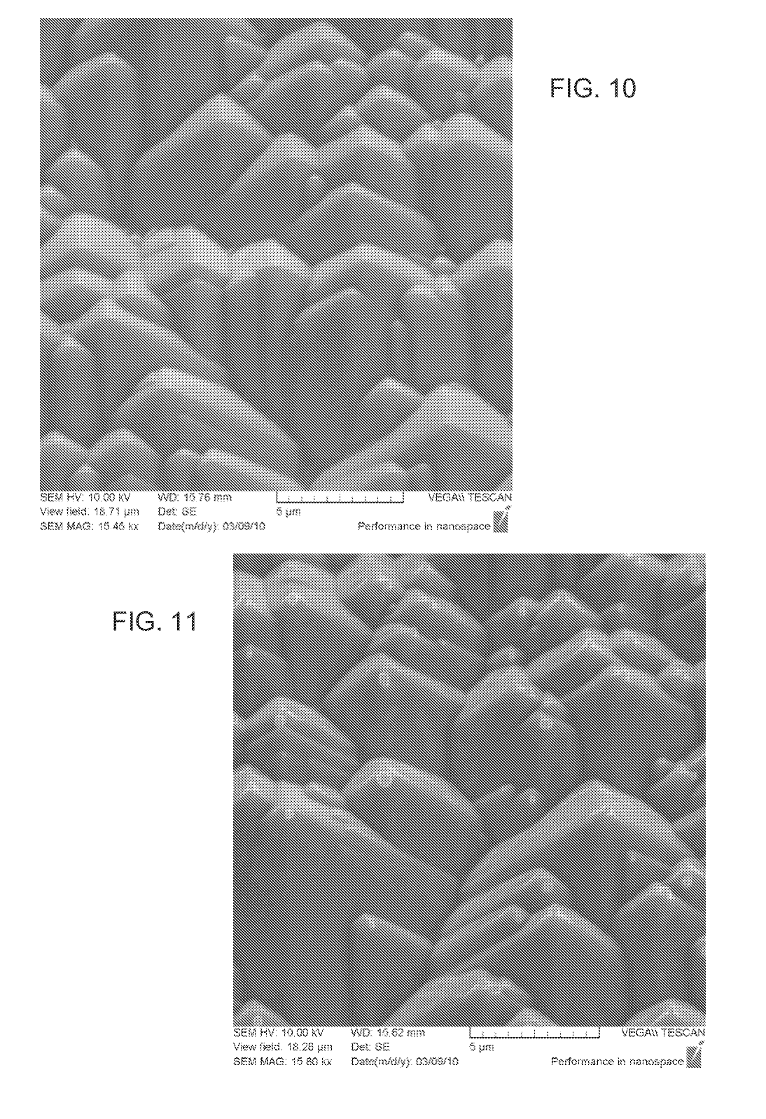

FIG. 10 Scanning electron microscope image of a semiconductor substrate with surface texturing before carrying out the method according to the invention

FIG. 11 Scanning electron microscope image of a semiconductor substrate with surface texturing after carrying out the method according to the invention

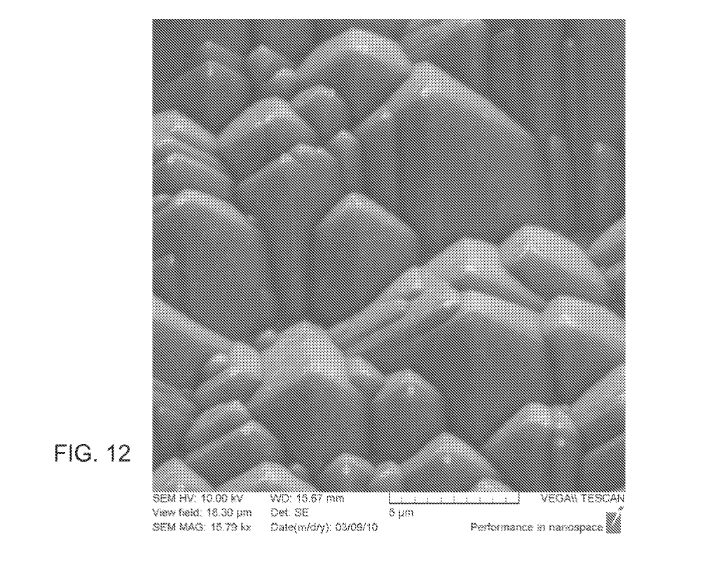

FIG. 12 Scanning electron microscope image of a semiconductor substrate with surface texturing after carrying out the method according to the invention.

FIG. 1 shows a simplified diagram of a first embodiment of the method according to the invention. In this case, firstly a surface texturing is formed 10 on a solar cell substrate used as a semiconductor substrate. This is followed by a phosphorus diffusion 12, in which lighter doping is formed on the surface of the solar cell substrate in planar fashion. The phosphorus diffusion 12 can take place in the way known in the art, for example by means of a POCl₃ pipe diffusion. Alternatively, for example, a phosphorus-containing solution can be spin-coated onto a front side of the solar cell substrate and dopant from this solution diffused into the solar cell substrate. As already explained above, the method according to the invention is, however, not limited to the use of phosphorus or another n-type dopant. In principle, p-dopings can also be used, for example instead of phosphorus diffusion 10 a boron diffusion can be provided.

In the embodiment from FIG. 1, during the phosphorus diffusion 12 a phosphorus-silicate glass layer can be formed, which is referred to henceforth as a P-glass layer for short. This is subsequently irradiated with laser radiation 14 in metallisation regions of the front side of the solar cell substrate, i.e. those regions in which the front side metallisation of the solar cell will later be arranged. FIG. 4 gives an impression of such an irradiation procedure. This shows a solar cell substrate 50, on which a P-glass layer is arranged on the front side, which is at the top. This P-glass layer 54 may, for example, have been formed in the phosphorus diffusion 12 described above. In the phosphorus diffusion 12, dopant from the P-glass layer 54 has already been diffused into the solar cell substrate 50 and in this way a continuous, less heavily doped region 56 has been formed. In the schematic diagram in FIG. 4 the P-glass layer 54 is irradiated in an irradiated region 62 with laser radiation 60. As a result the P-glass layer 54, as well as an adjacent region close to the surface 52 of the substrate 50, is locally heated. The heating of the solar cell substrate 50 in the heated region 52 can thereby take place through absorption of laser radiation 60 and/or heat transfer effects from the P-glass layer 54 to the solar cell substrate 50. As a result of the described local heating of the P-glass layer 54 and of the solar cell substrate 50 in the heated region 52, phosphorus is diffused out of the P-glass layer 54 into the heated region 52 of the solar cell substrate 50, so that a more heavily doped region 58 is formed there. This represents a diffusion 18 of dopant from the P-glass layer 54 into the solar cell substrate 50 in the sense of the diagram in FIG. 1.

In the embodiment of the method according to the invention shown in FIG. 1, in the course of the irradiation 14 of the P-glass layer, the solar cell substrate is melted 16 in a surface portion of less than 10% of the irradiated total area. Transferred to the diagram in FIG. 4, this means that a part of the heated region 52 is melted. In the further course of the method in accordance with FIG. 1, the melted parts of the solar cell substrate are recrystallised 20. This is followed by removal of the P-glass layer. In addition, the front side of the solar cell substrate is provided with a silicon nitride coating 24. Then the metallisation regions, in which more heavily doped regions have been formed, are metallised 26. This metallisation can in principle take place in any way known in the art. For preference, metallic pastes are applied to the metallisation regions, in particular by means of printing processes known in the art, such as for example screen printing processes, and sintered in. In this way, using the method according to the diagram in FIG. 1, a solar cell with a selective emitter can advantageously be formed.

FIG. 2 shows a further embodiment of the method according to the invention. This differs from the method according to FIG. 1 in that the melting 16 of the solar cell substrate is completely omitted. Consequently, as has already been explained above, a lesser reduction of the sheet resistance ensues in the heated regions of the solar cell substrate, but the contact resistance can be reduced sufficiently to achieve a good electrical contact between the solar cell substrate and contacts applied during metallisation 26, thus a correspondingly lower contact resistance. At the same time there is no longer the risk that when recrystallisation occurs, melted regions of the solar cell substrate will form structural defects or undesirable impurities will be input into the solar cell substrate, which would have a negative effect on the efficiency of the solar cell.

The illustration of the less heavily 56 and the more heavily doped regions 58 is to be understood accordingly by means of the broken line in FIG. 4. The more heavily doped region 58 can merely exhibit an altered contact resistance compared with the less heavily doped region 56. In addition, the more heavily doped region 58 can also be distinguished from the less heavily doped region 56 in that the sheet resistance in the more heavily doped region 58 is reduced by comparison with the sheet resistance value prevailing in the less heavily doped region 56. The amount of the reduction in the sheet resistance in the more heavily doped region depends on the extent to which the solar cell substrate is melted and recrystallised in the heated region 52. This is shown by the diagram in FIG. 6 and has been explained in more detail above.

In FIGS. 3 and 4, for the sake of clarity, an illustration of any surface texturing has been omitted. In principle, the solar cell substrate 50 can have surface texturing both in the irradiation variant in FIG. 3 and in the irradiation variant in FIG. 4, but this is not essential.

The variant embodiments of the irradiation according to FIG. 3 differs from the irradiation variant according to FIG. 4 in that in the variant according to FIG. 3, the solar cell substrate 50 is directly irradiated with laser radiation 60. As dopant source, in this case, instead of the P-glass layer 54 known from FIG. 4, a dopant-containing atmosphere could be used, from which dopant is diffused into the heated region 52. The method according to the invention can thus be flexibly used both with coated and uncoated solar cell substrates.

The surface texturing according to the variant embodiments in FIGS. 1 and 2 can, for example, be formed by wet-chemical texture etching of the solar cell substrate. Either alkaline or acid texture etching solutions can be used for this. Surface texturing produced using acid texture etching solutions are sometimes referred to as isotextures. FIG. 5 shows, in the left half of the image, in two schematic partial views a) and b), a surface texture, as can be formed using an alkaline texture etching solution on a monocrystalline silicon disc. Partial view a) shows a top view of such a surface texturing 73, while partial view b) is a perspectival view of this surface texturing 73. The pyramid structures of the surface texturing 73 which are generated typically have a height, referred to as texture height h, in the region of 3 μm to 15 μm. The invention can also be used unchanged with multicrystalline materials, in particular multicrystalline silicon materials. In that case, instead of the pyramid structures shown in FIG. 5, depending on the etching solution used, surface texturings are produced with different geometrical forms. Acid texture etching solutions have proven especially effective in the production of surface texturings on multicrystalline silicon materials.

The partial views a) and b) in FIG. 5 show the surface texturing 73 before the method according to the invention is carried out. If the melting of the semiconductor substrate under irradiation with laser radiation is omitted when carrying out the method according to the invention, these partial views a) and b) also reflect the condition of the surface texturing after carrying out the method according to the invention. In that case, structure tips 74 of the surface texturing 73 have not been melted.

In another variant embodiment of the method according to the invention, however, the structure tips 74 of the surface texturing are melted over a cross-sectional area 78. Partial views c) and d) show the result of carrying out the method in this way. Instead of the tapering pointed structure tips 74 in partial views a) and b), there are now melted and recrystallised structure tips 76. In one advantageous variant embodiment of the method according to the invention the structure tips of the surface texturing 73 are melted over a cross-sectional area 78 which is less than 1 μm², preferably less than 0.25 μm². The fact that this can be realised is illustrated by FIG. 7, which shows a scanning electron microscope image of a surface texturing after carrying out the method according to the invention. As can be seen herein, the structure tips have not been melted or at most only very slightly. The situation described can be seen better in the images with greater magnification in FIGS. 10 to 12. While FIG. 10 shows a scanning electron microscope image of a surface texturing before carrying out the method according to the invention, FIGS. 11 and 12 show scanning electron microscope images of surface texturings after carrying out the method according to the invention. As can be seen in FIGS. 11 and 12, when carrying out the method according to the invention, the structure tips have been very slightly melted, or not at all.

FIG. 8 shows in schematic view an embodiment of the solar cell 70 according to the invention. This has a solar cell substrate 50 which is preferably formed by a silicon disc. As can be seen in the schematic lateral view in FIG. 8, the solar cell 70 has a two-stage doping, which is formed by the more heavily doped region 58 and less heavily doped regions 56. The more heavily doped region 58 thereby differs from the less heavily doped regions 56 in that a lesser contact resistance prevails in the more heavily doped region 58. Also, the sheet resistance in the more heavily doped region can be reduced by comparison with the less heavily doped regions. Preferably, the solar cell according to the invention in FIG. 8 has a contact resistance of 10 mΩcm² or less in the more heavily doped region 58. The sheet resistance in the more heavily doped regions 58 is at least 50% of the sheet resistance value prevailing in less heavily doped regions, preferably at least 70% of this value and especially preferably 90% or more of the sheet resistance value prevailing in less heavily doped regions. In this way a comparatively high spectral sensitivity is realised in the more heavily doped regions.

As shown by the lateral view in FIG. 8, a metallisation 72 arranged on the more heavily doped region 58 is narrower than the heavily doped region 58. As explained above, this reduces the requirement for adjustment and/or accuracy of orientation of the metallisation 72 relative to the heavily doped region 58, which increases the stability of the manufacturing process and the reduces the risk of rejects.

FIG. 9 shows, in a top view, an enlarged partial view of the partial region A of the solar cell 70 from FIG. 8. As can be seen here, the solar cell 70 has a surface texturing 73. Its structure tips 76 are intact in the left half of the image. This left half of the image shows the surface texturing 73 in a less heavily doped region 56. As indicated by a broken line, this is adjacent the more heavily doped region 58. The more heavily doped partial region 58 is, as again indicated by a broken line, partially overlapped by the metallisation 72. In the more heavily doped region 58, the structure tips 76 of the surface texturing 73 are melted and recrystallised over a cross-sectional area 78 of less than 1 μm², preferably of less than 0.25 μm². The less the sheet resistance in the more heavily doped region 58 is reduced compared with the sheet resistance value prevailing in the less heavily doped region 56, the higher the spectral sensitivity of the solar cell substrate in those partial regions of the more heavily doped regions 58 which are not covered by the metallisation, which has a positive effect on the efficiency of the solar cell 70.

The illustrations in FIGS. 8 and 9 are simplified diagrams. It is therefore obvious that the number, form and geometry of the more heavily doped regions 58, as well as the metallisations 72, must be adapted to the respective application.

In the case of the method according to the invention and also in the case of the solar cell according to the invention, monocrystalline or multicrystalline materials can be used as semiconductor- or solar cell substrate, in particular monocrystalline or multicrystalline silicon materials.

### LIST OF REFERENCE NUMBERS

10 formation of surface texturing

12 phosphorus diffusion

14 irradiation with laser radiation

16 melting the solar cell substrate

18 diffusion dopant

20 recrystallisation

22 removal of P-glass

24 silicon nitride coating

26 metallisation

50 solar cell substrate

52 heated region

54 P-glass layer

56 less heavily doped region

58 more heavily doped region

60 laser radiation

62 irradiated region

70 solar cell

72 metallisation

73 surface texturing

74 structure tips

76 melted and recrystallised structure tips

78 cross-sectional area

h texture height

SiN silicon nitride

1-13. (canceled)

14. A method for doping a semiconductor substrate, the method which comprises:
heating the semiconductor substrate by irradiation with laser radiation and simultaneously diffusing dopant from a dopant source into the semiconductor substrate in heated regions thereof;
while heating the semiconductor substrate by the irradiation with laser radiation, melting and recrystallizing a surface portion of the semiconductor substrate amounting to less than 10% of a total surface of all irradiated regions.

15. The method according to claim 14, which comprises heating the semiconductor substrate locally by local irradiation with laser radiation and diffusing the dopant locally into the heated regions.

16. The method according to claim 14, which comprises melting and recrystallizing the semiconductor substrate in a surface portion of less than 5% of the total surface of all irradiated regions.

17. The method according to claim 14, wherein the semiconductor substrate is not melted during irradiation with laser radiation.

18. The method according to claim 14, which comprises reducing in heated regions a contact resistance of the semiconductor substrate to 10 mΩcm² or less, and reducing a sheet resistance of the semiconductor substrate by 50% or less compared to a value prevailing before the diffusion of the dopant.

19. The method according to claim 18, which comprises reducing the sheet resistance of the semiconductor substrate by 30% or less compared to the value prevailing before the diffusion of the dopant.

20. The method according to claim 18, which comprises reducing the sheet resistance of the semiconductor substrate by 10% or less compared to the value prevailing before the diffusion of the dopant.

21. The method according to claim 14, which comprises using a semiconductor substrate that is at least partially provided with surface texturing and melting structure tips of the surface texturing over a cross-sectional area of less than 1 μm².

22. The method according to claim 21, which comprises melting the structure tips of the surface texturing over a cross-sectional area of less than 0.25 μm².

23. The method according to claim 14, which comprises irradiating the semiconductor substrate with pulsed laser radiation having a pulse energy density of less than 2 J/cm².

24. The method according to claim 14, which comprises irradiating the semiconductor substrate with pulsed laser radiation having a pulse length of between 20 ns and 500 ns.

25. The method according to claim 24, wherein the laser radiation has a pulse length of between 100 ns and 300 ns.

26. The method according to claim 14, which comprises generating the laser radiation with a diode-pumped solid-state laser.

27. The method according to claim 15, which comprises, as a result of local diffusion of dopant into the heated regions, forming more heavily doped regions of a two-stage doping.

28. The method according to claim 27, wherein the semiconductor substrate is a solar cell substrate and applying a metallization layer in more heavily doped regions of the two-stage doping.

29. A solar cell, comprising:
a solar cell substrate formed, at least partially, with surface texturing and a two-stage doping;
the two-stage doping including more heavily doped regions wherein structure tips of said surface texturing are melted and recrystallised over a cross-sectional area of less than 1 μm².

30. The solar cell according to claim 29, wherein the structure tips of the surface texturing are melted and recrystallized over a cross-sectional area of less than 0.25 μm².

31. The solar cell according to claim 29, wherein said solar cell substrate
has a contact resistance of 10 mΩcm² or less in the more heavily doped regions of said two-stage doping; and
in the more heavily doped regions of the two-stage doping, has a sheet resistance that is at least 50% of a sheet resistance value prevailing in less heavily doped regions of the two-stage doping.

32. The solar cell according to claim 31, wherein said solar cell substrate has a sheet resistance that is at least 70% of a sheet resistance value prevailing in less heavily doped regions of the two-stage doping.

33. The solar cell according to claim 31, wherein said solar cell substrate has a sheet resistance that is at least 90% of a sheet resistance value prevailing in less heavily doped regions of the two-stage doping.
